(19) United States
(12) Patent Application Publication
(10) Pub. No.: US 2011/0181315 A1
(43) Pub. Date: Jul. 28, 2011

(54) Adaptive Device Aging Monitoring and Compensation

(75) Inventor: Musaravakkam Krishnan, Cupertino, CA (US)

(73) Assignee: Broadcom Corporation, Irvine, CA (US)

(21) Appl. No.: 12/693,199

(22) Filed: Jan. 25, 2010

(51) Int. Cl. G01R 31/26; G01R 31/02

(52) U.S. Cl. 324/762.01

(57) ABSTRACT

Improved device aging monitoring and compensation schemes are presented herein. In particular, embodiments enable quantitative measurement of actual aging experienced by a device up to the instant of measurement, rather than rely on static a priori estimation of aging effects under worst case conditions. As such, embodiments provide adaptive device aging monitoring and compensation schemes. In addition, embodiments allow for aging monitoring and compensation to be performed at a desired granularity, whereby aging monitoring and compensation can be performed at a chip, module, or sub-module level. Further, embodiments inherently compensate for the effects of aging on passive components (e.g., parasitics of interconnect wires, capacitors, etc.) in addition to active device aging.

### BACKGROUND

1. Field of the Invention

The present invention relates generally to device aging monitoring and compensation.

2. Background Art

Device aging (particularly in submicron geometries) results in the degradation of the electrical parameters of a semiconductor device during its normal operation. Further, the effects of device aging become more pronounced as the device geometry gets smaller.

Conventional aging compensation schemes estimate a priori the effects of aging on key parameters of the device. Then, based on a worst case aging scenario, device aging effects are accounted for in the design of the device by including adequate design margins such that the device meets its design requirements if the full effects of aging manifest themselves near the end of the device's operating life.

As a result, conventional aging compensation schemes lead to conservative design practices and to heavily guard-banding several design parameters, which result in significant performance loss. Further, conventional schemes do not have a reliable method to quantitatively measure the effects of aging in a device as aging progresses.

Accordingly, there is a need for improved device aging monitoring and compensation schemes.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIGS. 1A and 1B illustrate examples of a System on Chip (SoC) that implements an aging monitoring scheme according to an embodiment of the present invention.

FIGS. 2A and 2B illustrate examples of an SoC that implements an aging compensation scheme according to an embodiment of the present invention.

FIG. 3A is a circuit schematic of an inverter circuit.

FIG. 3B is cross-sectional view of an inverter circuit.

The present invention will be described with reference to the accompanying drawings. Generally, the drawing in which an element first appears is typically indicated by the leftmost digit(s) in the corresponding reference number.

### DETAILED DESCRIPTION OF EMBODIMENTS

Device aging (particularly in submicron geometries such as 65 nm and beyond) results in the degradation of the electrical parameters of a device during its normal operation. For example, Hot Carrier Injection (HCI) is an aging phenomenon that results from charges collecting in a transistor's gate insulation, and which results in raising the voltage at which a device starts conducting (i.e., threshold voltage). Negative Bias Temperature Instability (NBTI) has similar effect on the device threshold voltage and occurs when a transistor is conducting. NBTI is caused by charge traps forming at the interface between a transistor's conduction channel and the gate insulation. NBTI's effects are most significant for devices that use high-k gate dielectric and metal gates. Time-Dependent Dielectric Breakdown (TDDB) is yet another aging phenomenon with very serious effects. TDDB results from defects accumulating within the gate insulation, ultimately forming a short circuit and causing failure of the transistor.

Typically, the effects of device aging become more pronounced as the device geometry gets smaller. For example, at a supply voltage of V_{cc}=1.2V, the lifetime of a 40LP device is about 4 to 30 times shorter than that of a 65LP device operating at the same voltage. Other factors also determine the actual effects of aging. For example, a semiconductor device is known to “recover” from NBTI effects when the biasing of its gate relative to its source/drain is no longer static (“DC”) and becomes dynamic (“AC”).

Conventional aging compensation schemes estimate a priori the effects of aging on key parameters of the device. Then, based on a worst case aging scenario, device aging effects are accounted for in the design of the device by including adequate design margins such that the device meets its design requirements if the full effects of aging manifest themselves near the end of the device's operating life.

As a result, conventional aging compensation schemes lead to conservative design practices and to heavily guard-banding several design parameters (e.g., maximum frequency of operation, minimum supply voltage, etc.), which result in significant performance loss. Further, conventional schemes do not have a reliable method to quantitatively measure the effects of aging in a device as aging progresses. Furthermore, there is strong evidence that suggests that recovery from NBTI effects is not linear with time and is more pronounced early in the life of the device. However, the difficulty of accurately predicting and accounting for such time-variant behavior requires the incorporation of adequate design margin in the parameters of a device during its design phase, i.e., before it is committed to fabrication and manufacture. Consequently, these devices are constrained from utilizing their maximum possible performance optimally at any given point during their operating life.

Embodiments of the present invention provide improved device aging monitoring and compensation schemes, which may be independent of each other. In particular, embodiments enable quantitative measurement of actual aging experienced by a device up to the instant of measurement, rather than relying on static a priori estimation of aging effects under worst case conditions. As such, embodiments provide adaptive device aging monitoring and compensation schemes. In addition, embodiments allow for aging monitoring and compensation to be performed at a desired granularity, whereby aging monitoring and compensation can be performed at a chip, module, or sub-module level. These embodiments also enable aging monitoring and compensation to be performed at pre-designated events such as at system boot or upon the completion of a time interval. Further, embodiments inherently compensate for the effects of aging on passive components (e.g., parasitics of interconnect wires, capacitors, etc.) in addition to active device aging.

Further, embodiments automatically account for the various factors that affect aging, such as device switching, threshold voltage variations due to implant/doping variations, device size, channel length variations (from their intended target values) due to lithography/eBeam tolerances, junction temperature variations due to local power dissipation profiles, etc.

Embodiments can be used in any system on chip (SoC) device that is subject to the effects of semiconductor aging, including, but not limited to, SoCs found in cellular phones, portable media players, 2G/3G modem devices, consumer electronics, headsets, connectivity, and computer processors.

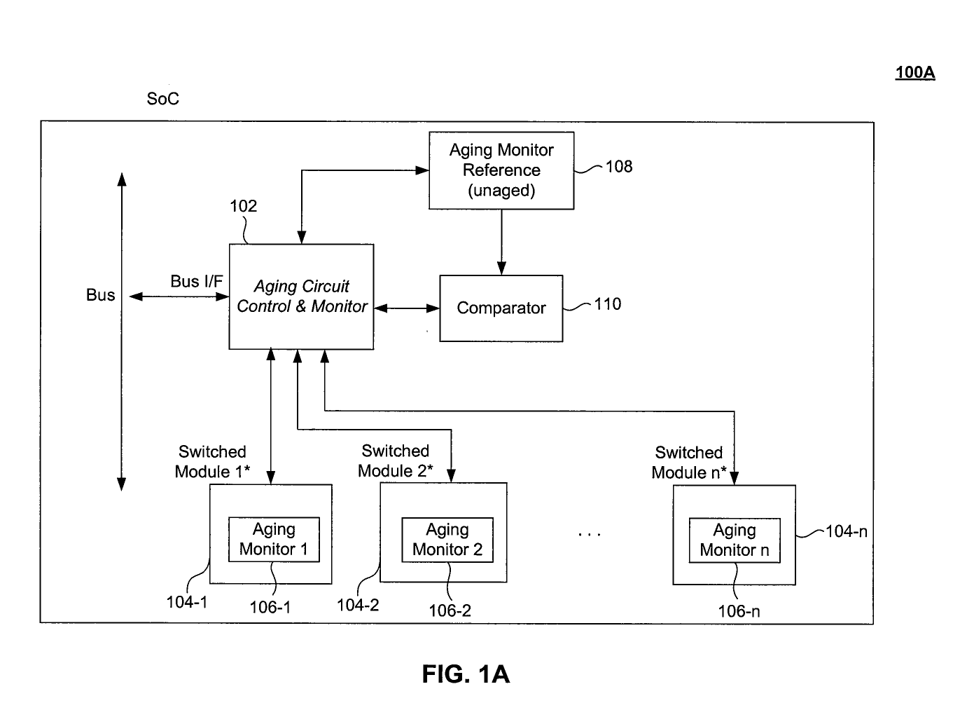

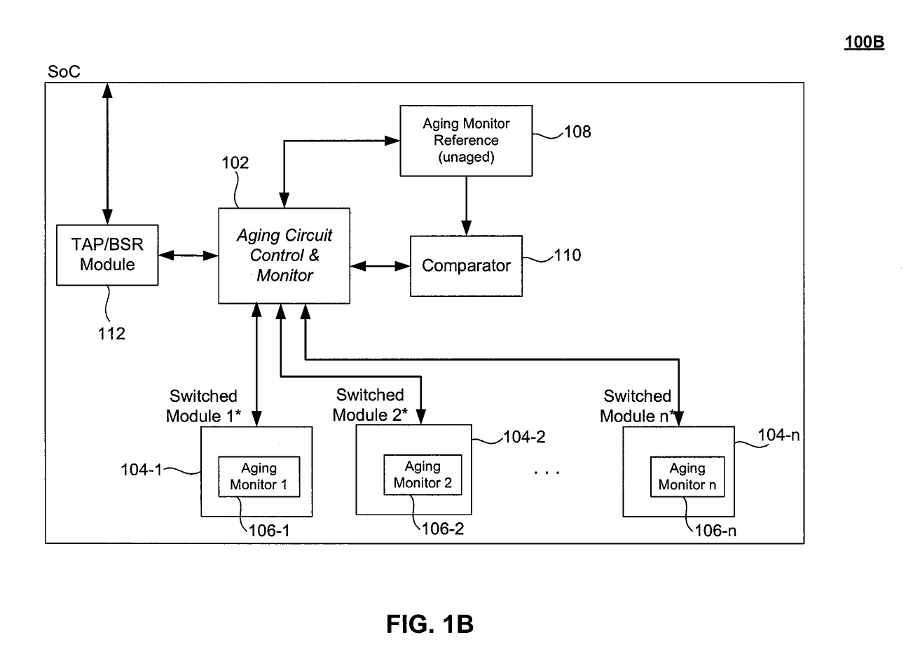

FIG. 1A is an example system on chip (SoC) 100A that implements an aging monitoring scheme according to an embodiment of the present invention.

In an embodiment, the aging monitoring scheme of SoC 100A is based on measuring the differences due to aging between two instances of the same circuit, one that ages with normal operation of SoC 100A and one that is kept “un-aged.” The aging monitoring scheme can be applied at the SoC, module, or sub-module level, and can be tailored for each level according to feasibility, effectiveness, and cost. In an embodiment, measurements are performed on a periodic basis, based on a usage duty cycle of the SoC, module, or sub-module, or based on events occurring in the SoC, module, or sub-module. Further, the aging monitoring scheme can be tailored according to the application(s) being executed by the SoC, module, or sub-module. For example, the aging monitoring scheme can be tailored according to the operating frequencies of the application(s) that execute on the SoC, module, or sub-module (applications may have different operating frequencies, and the aging monitoring scheme may be tailored accordingly). The specific type of circuit that is the subject of these measurements is not relevant to the aging monitoring scheme described herein. In an embodiment, the circuit is a ring oscillator, but other circuits may also be used.

In an implementation, as shown in FIG. 1A, SoC 100A includes an aging control and monitoring module 102, a plurality of switched modules 104 each having a respective aging monitor circuit 106, a reference aging monitor circuit 108, and a comparator module 110. Thus, the aging monitoring scheme is performed at a module level in SoC 100A.

Aging control and monitoring module 102 monitors the aging of each of switched modules 104. Accordingly, in an embodiment, module 102 includes means for communicating with each of aging monitor circuits 106, reference aging monitor circuit 108, and comparator module 110. Module 102 communicates with aging monitor circuit 106 to retrieve measurements indicative of the aging of aging monitor 106 (and by association of switched module 104). Module 102 also communicates with reference aging monitor circuit 108, to retrieve corresponding measurements regarding reference aging monitor circuit 108, or to instruct reference aging monitor circuit 108 to forward the measurements to comparator module 110. The measurements can include circuit performance parameters that historically change with circuit use and/or age (e.g., propagation delay, leakage current, analog circuit parameters, etc.). Module 102 can be implemented using hardware and/or software.

Reference aging monitor circuit 108 is identical to aging monitor circuit 106 notwithstanding unintended process variations between the two circuits (i.e., reference aging monitor circuit 108 and aging monitor circuit 106 are instances of the same circuit and are expected to age identically). Therefore, differences between the two sets of measurements represent the aging of aging monitor circuit 106 (and switched module 104 associated therewith) relative to reference aging monitor circuit 108. Further, because reference circuit 108 is kept un-aged the differences also represent the actual aging of aging monitor circuit 106. It is noted that the specific circuit that is used for circuits 106 and 108 is not relevant to the aging monitoring scheme. In an embodiment, the circuit is a ring oscillator, though other circuits may also be used. In an embodiment, the specific circuit used depends on the particular circuit parameters for which aging effects are of interest. Further, aging monitor circuit 106 and reference circuit 108 may be tailored according to the specific fabrication technology of the SoC (or SoC module) that they are associated with. For example, aging monitor circuit 106 and reference circuit 108 may be designed to be reflective of the specific makeup of the SoC (or SoC module) (e.g., circuits 106 and 108 may be tailored to reflect a high percentage of high V_{T} devices in the SoC or a high percentage of long channel PMOS transistors in the SoC).

Module 102 uses comparator module 110 to calculate the differences between the two sets of measurements (i.e., the measurements from circuit 106 and the measurements from circuit 108), and thus quantitatively measure the aging effects of switched module 104 based on the two sets of measurements. In an embodiment, comparator module 110 accounts for process variations between circuits 106 and 108 in measuring the differences between the two sets of measurements. For example, process variations are measured a priori before the application of the aging monitoring scheme.

It is noted that a switched module 104 in SoC 100A represents a group of units (e.g., transistors, gates, circuits, etc.) that operate together to perform a given function within SoC 100A (e.g., transceiver function, audio and/or video processing, power measurement, etc.). Switched modules 104-{1, . . . , n} may perform different functions and thus may age differently. Accordingly, for better aging monitoring, SoC 100A implements aging monitoring at the module level, where each switched module 104 is associated with a respective aging monitor circuit 106. Whenever a switched module 104 is activated, the corresponding aging monitor circuit 106 associated with it is also activated. It is noted, however, that aging monitor circuit 106 is typically not engaged in the intended functionality of its respective switched module 104, but is instead intended to measure the collective aging of circuits of switched module 104 that do support the intended functionality of switched module 104. In an embodiment, the above described aging monitoring scheme is applied for each switched module 104 independently of the other switched modules. In another embodiment, the aging monitoring scheme is performed periodically for all switched modules, periodically for each switched module independently of the other modules, based on the individual usage of each switched module, or collectively for modules with similar aging attributes, e.g., modules that age in proportion with the activity level of the module.

In another embodiment, the aging monitoring scheme inside the SoC can be enabled and controlled without the need for any processor or dedicated hardware but through standard Input/Output (I/O) ports/pins of the SoC using the Standard Test Access Port (TAP) and Boundary-Scan Architecture. In this embodiment, as illustrated in FIG. 1B, standard I/O ports are used to shift in via TAP/BSR module 112 the appropriate control sequences that enable or disable any of aging monitors 106-{1, . . . , n} in switched modules 104-{1, . . . , n} and reference aging monitor circuit 108. This embodiment is particularly useful in applications where the given SoC is being characterized for its long-term aging behavior using environments that may not be conducive to the normal operation of the SoC. Examples of such characterization environments are High Temperature Operating Life (HTOL) characterization schemes. In such schemes, the SoC is subjected to accelerated aging by controlling its electrical stress levels with minimal external control/support, and changes in key attributes of the SoC such as delay degradation, analog parameters, etc. are monitored periodically (at pre-designated “read points”).

As noted above, SoC 100A implements the aging monitoring scheme at the module level. In other embodiments, the scheme may be implemented at the SoC level for lower cost and power consumption or at the sub-module level for higher granularity, and can be further tailored for each level according to feasibility, effectiveness, and cost.

Embodiments further include an aging compensation scheme which will be described below. The aging compensation scheme combines with the aging monitoring scheme described above to cancel out the effects of aging on the performance of SoC 100A and its switched modules 104. As with the aging monitoring scheme, the aging compensation scheme can be applied at different levels within SoC 100A and can be tailored at each level according to feasibility, effectiveness, and cost.

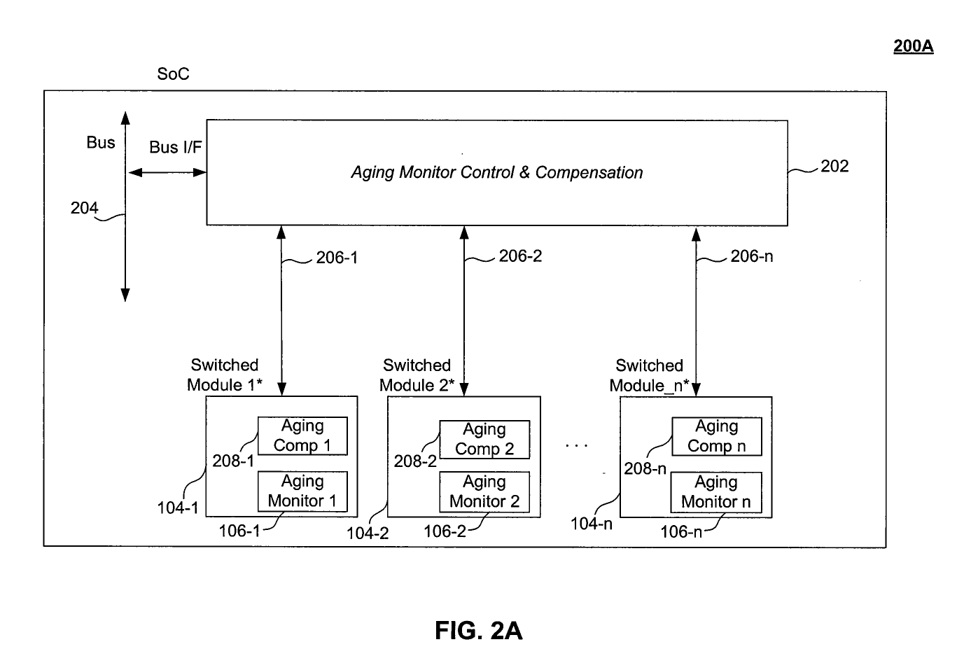

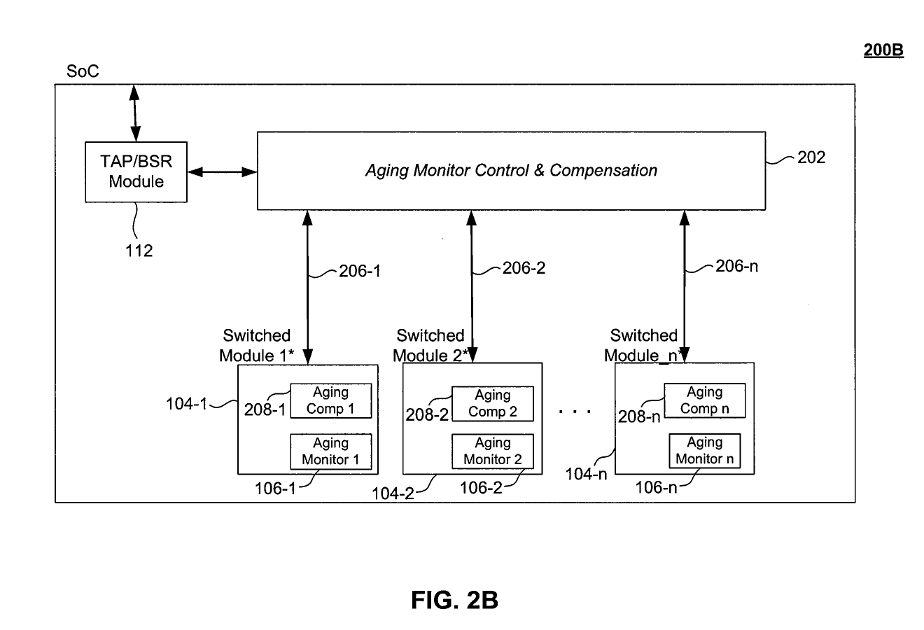

FIG. 2A illustrates an example SoC 200A that implements an aging compensation scheme according to an embodiment of the present invention. SoC 200A also implements an aging monitoring scheme according to an embodiment of the present invention. The aging monitoring scheme of SoC 200A is similar to the scheme described above with respect to FIGS. 1A and 1B and thus will not be described herein.

As shown in FIG. 2A, SoC 200A includes an aging monitoring control and compensation module 202, and a plurality of switched modules 104 each having a respective aging monitor circuit 106 and a respective aging compensation circuit 208. SoC 200A may also include a reference aging monitor circuit 108 and a comparator module 110 (not shown in FIG. 2A) to support the aging monitoring scheme of SoC 200A.

Aging monitoring control and compensation module 202 communicates with each of switched modules 104 using respective interfaces 206. Aging monitoring control and compensation module 202 may also be connected to a internal bus 204 that allows switched modules 104 to communicate with external modules.

In an embodiment, module 202 includes a sub-module similar to aging control and monitoring module 102 described above that performs aging monitoring functions. In addition, module 202 includes a sub-module that determines appropriate aging compensation to be applied to each switched module 104 based on quantitative aging effects calculated by the aging monitor sub-module. Accordingly, in an embodiment, module 202 communicates with aging monitor circuit 106 to retrieve measurements indicative of the aging of switched module 104, and also communicates with aging compensation circuit 208 to apply appropriate aging compensation to switched module 104 in response to the measured aging of switched module 104.

According to embodiments, the means and amount of aging compensation applied to switched modules 104 may differ from one switched module 104 to another. In an embodiment, aging compensation depends on the aging effects detected in a particular switched module 104 and/or the particular circuit parameters for which aging effects are of interest. Aging compensation may also vary depending on the nature of the circuit being compensated (e.g., analog versus digital) and/or the specific function performed by the particular circuit. Furthermore, according to embodiments, the particular attributes that are unique to SoC 200A as a whole (e.g., fabrication process corner, applications that run on SoC 200A during its lifetime, etc.) may also be incorporated in determining aging compensation.

FIG. 2B illustrates another example SoC 200B according to an embodiment of the present invention. Example SoC 200B is similar to SoC 200A described above. However, instead of using an internal bus, example SoC 200B uses a TAP/BSR module 112, which can be used by module 202 to communicate directly with the SoC ports.

Example aging compensation methods according to embodiments will now be presented. These methods are presented for the purpose of illustration and not limitation.

As described above, device aging in a transistor affects the threshold voltage of the transistor. This in turn affects the propagation delay through the transistor. In particular, a lower threshold voltage has the effect of lowering the propagation delay through the transistor, while a higher threshold voltage has the opposite effect and also reduces leakage current through the transistor (i.e., the current that flows through the transistor when the transistor is “OFF”).

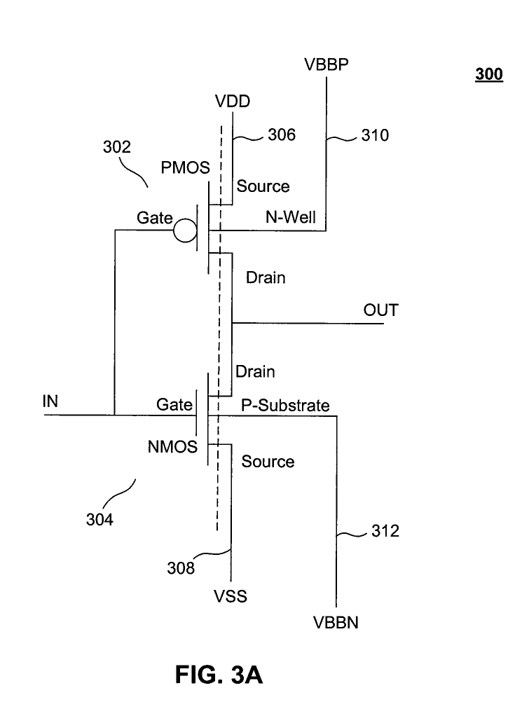

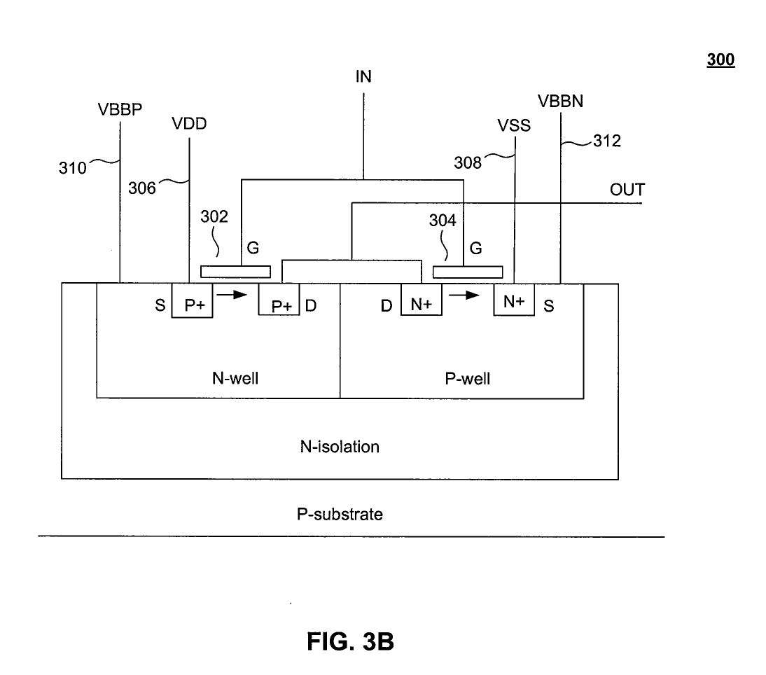

According to an embodiment, device aging in a transistor with respect to threshold voltage can be monitored by monitoring changes in the propagation delay of the transistor. If changes from a nominal value are detected, then aging compensation is applied. In an embodiment, aging compensation is applied using a body biasing technique, further described below with reference to an example inverter circuit in FIGS. 3A and 3B.

FIG. 3A is a circuit schematic of an inverter circuit 300. A cross-sectional view of inverter circuit 300 is shown in FIG. 3B. As shown in FIGS. 3A and 3B, inverter circuit 300 includes a PMOS transistor 302 coupled in series with an NMOS transistor 304 between a VDD 306 and a VSS 308 voltage levels. PMOS transistor 302 and NMOS transistor 304 have a common gate terminal, which provides an input signal to inverter circuit 300. In addition, PMOS transistor 302 and NMOS transistor 304 have a common drain terminal, which provides an output terminal of inverter circuit 300.

PMOS transistor 302 is embedded in an N-well region. The bulk region of PMOS transistor 302 is coupled to a VBBP 310 voltage. Generally, VBBP 310 is equal to VDD 306 so that the N-well region embedding PMOS transistor 302 is at the same voltage as the source terminal of PMOS transistor 302. NMOS transistor 304 is embedded in a P-well region. The bulk region of NMOS transistor 304 is coupled to a VBBN 312 voltage. Generally, VBBN 312 is equal to VSS 308 so that the P-well region embedding NMOS transistor 304 is at the same voltage as the source terminal of NMOS transistor 304.

Body biasing according to embodiments includes applying a voltage between the gate and substrate (i.e., bulk) of a transistor in order to modify its switching threshold voltage (or equivalently its propagation delay, leakage current, etc.). In particular, with reference to FIGS. 3A and 3B, body biasing includes making VBBN 312>VSS 308 or VBBP 310<VDD 306 in order to lower the respective threshold voltages of NMOS transistor 304 and PMOS transistor 302. Conversely, body biasing includes making VBBN 312<VSS 308 or VBBP 310>VDD 306 in order to increase the respective threshold voltages of NMOS transistor 304 and PMOS transistor 302.

As mentioned above, the threshold voltage of a transistor directly affects the propagation delay through the transistor and the leakage current of the transistor. Thus, both the propagation delay and the leakage current can also be adjusted using body biasing to compensate for aging effects.

In another embodiment, aging compensation is applied using an adaptive voltage scheme (AVS), which dynamically adjusts the supply voltage of the SoC (or its individual modules and sub-modules) as a function of its aging. In a further embodiment, AVS is used to extend the useful life of the SoC by dynamically adjusting the minimum and the maximum supply voltage in anticipation of expected aging of the SoC. In an embodiment, aging compensation is applied using a Dynamic Voltage and Frequency Scaling (DVFS) scheme which dynamically adjusts one or more of the minimum supply voltage and the maximum supply voltage applied to the SoC (or its individual modules and sub-modules) as a function of measured aging at the SoC. In another embodiment, DVFS includes, additionally or alternatively, dynamically adjusting the operating frequency of the SoC as a function of detected aging of the SoC. In a further embodiment, DVFS is used to extend the useful life of the SoC by dynamically adjusting the minimum/maximum supply voltage and/or operating frequency in anticipation of expected aging of the SoC.

In another embodiment, the aging monitoring scheme is applied to analog circuits based on a correlation (established a priori) between selected analog circuit parameter(s) of interest and the switching threshold of a transistor which is measured by the scheme described herein.

As would be understood by a person skilled in the art based on the teachings herein, aging compensation schemes according to embodiments of the present invention may be implemented using a combination of digital and analog components. For example, both body biasing and AVS or DVFS may use digital hardware to calculate the voltages and/or operating frequency to be applied to the SoC, and analog modules, submodules or components that translate the digital hardware output into analog signals.

In addition, various aspects of embodiments of the present invention can be implemented using software, firmware, hardware, or a combination thereof. For example, the representative signal processing functions described herein (e.g. device aging measurement, comparator functions, device aging determination, etc.) can be implemented in hardware, software, or some combination thereof. For instance, the signal processing functions can be implemented using computer processors, computer logic, application specific circuits (ASIC), digital signal processors, etc., as will be understood by those skilled in the arts based on the discussion given herein. Accordingly, any processor that performs the signal processing functions described herein is within the scope and spirit of the present invention.

Further, the signal processing functions described herein could be embodied by computer program instructions that are executed by an instruction processor or any one of the hardware devices listed above. The computer program instructions cause the processor to perform the signal processing functions described herein. The computer program instructions (e.g. software) can be stored in a computer usable medium, computer program medium, or any storage medium that can be accessed by a computer or processor. Such media include a memory device such as a RAM or ROM, or other type of computer storage medium such as a hard drive or CD ROM, or the equivalent. Accordingly, any computer storage medium having computer program code that causes a processor to perform the signal processing functions described herein is within the scope and spirit of the present invention.

Embodiments can work with software, hardware, and/or operating system implementations other than those described herein. Any software, hardware, and operating system implementations suitable for performing the functions described herein can be used.

Embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of embodiments of the present invention should not be limited by any of the above-described exemplary embodiments, but should be defined only in accordance with the following claims and their equivalents.

What is claimed is:

1. A method for determining device aging in a system on chip (SoC), comprising:
(a) measuring a circuit parameter of interest in an aging monitor circuit embedded within the SoC, wherein the aging monitor circuit is active during normal operation of the SoC;
(b) comparing the measured circuit parameter with a reference circuit parameter of a reference circuit, wherein the reference circuit is identical to the aging monitor circuit and is inactive during normal operation of the SoC; and
(c) determining device aging within the SoC based on the comparison of the measured circuit parameter and the reference circuit parameter.

2. The method of claim 1, wherein the circuit parameter is representative of one or more of propagation delay, leakage current, and threshold voltage of a semiconductor device within the SoC.

3. The method of claim 1, wherein the aging monitor circuit is a ring oscillator circuit.

4. The method of claim 1, wherein the aging monitor circuit experiences similar device aging as the SoC.

5. The method of claim 1, wherein the aging monitor circuit is tailored according to the specific fabrication technology of the SoC.

6. The method of claim 1, wherein comparing the measured circuit parameter with the reference circuit parameter comprises:
determining a difference between the measured circuit parameter and the reference circuit parameter; and
adjusting the difference to account for process variations between the aging monitor circuit and the reference circuit.

7. The method of claim 1, further comprising:
(d) applying device aging compensation to the SoC in response to the determined device aging.

8. The method of claim 7, wherein applying device aging compensation includes body biasing one or more semiconductor devices of the SoC.

9. The method of claim 7, wherein applying device aging compensation includes dynamically adjusting one or more of the supply voltage and operating frequency of the SoC.

10. The method of claim 7, wherein applying device aging compensation includes dynamically adapting one or more of the minimum supply voltage and the maximum supply voltage applied to the SoC.

11. The method of claim 7, wherein applying device aging compensation includes adjusting attributes of passive components of the SoC.

12. The method of claim 7, wherein applying device aging compensation includes adjusting one or more of an interconnect capacitance and an interconnect resistance within the SoC.

13. The method of claim 7, wherein the aging monitor circuit is embedded within a functional module of the SoC, wherein the determined device aging is representative of device aging within said functional module, and wherein device aging compensation is applied to said functional module of the SoC.

14. The method of claim 13, wherein device aging compensation is tailored according to the particular function performed by the functional module within the SoC.

15. The method of claim 13, wherein device aging compensation is tailored according to whether the functional module is digital or analog.

16. The method of claim 13, wherein device aging compensation is tailored according to the specific fabrication technology of the SoC.

17. The method of claim 7, further comprising:
(e) repeating steps (a)-(d) periodically, thereby adaptively compensating device aging in the SoC.

18. The method of claim 7, further comprising:
(e) repeating steps (a)-(d) according to one or more of a usage duty cycle of the SoC and application(s) being executed by the SoC.

19. The method of claim 1, wherein the reference circuit is active during a device aging measurement cycle.

20. The method of claim 1, wherein the reference circuit is embedded within the SoC.

21. The method of claim 1, wherein the reference circuit is external to the SoC.

22. A system for determining device aging in a system on chip (SoC), comprising:
an aging monitor circuit embedded within the SoC, wherein the aging monitor circuit is active during normal operation of the SoC;
a reference circuit, wherein the reference circuit is identical to the aging monitor circuit and is inactive during normal operation of the SoC;
a comparator module that compares a circuit parameter of interest measured in the aging monitor circuit with a reference circuit parameter of the reference circuit; and
a control module that determines device aging within the SoC based on the comparison of the measured circuit parameter and the reference circuit parameter.

23. The system of claim 22, wherein the aging monitor circuit is a ring oscillator circuit.

24. The system of claim 22, wherein the aging monitor circuit experiences similar device aging as the SoC.

25. The system of claim 22, wherein the comparator module comprises:
means for determining a difference between the measured circuit parameter and the reference circuit parameter; and
means for adjusting the difference to account for process variations between the aging monitor circuit and the reference circuit.

26. The system of claim 22, wherein the control module further determines device aging compensation to be applied to the SoC in response to the determined device aging, the system further comprising:
an aging compensation module that applies the device aging compensation determined by the control module to the SoC.

27. The system of claim 26, wherein the aging compensation module comprises:
means for body biasing one or more semiconductor devices of the SoC.

28. The system of claim 26, wherein the aging compensation module comprises:
means for dynamically adjusting one or more of the supply voltage and operating frequency of the SoC.

29. The system of claim 26, wherein the aging compensation module comprises:
means for dynamically adapting one or more of the minimum supply voltage and the maximum supply voltage applied to the SoC.

30. The system of claim 22, wherein the aging monitor circuit is embedded within a functional module of the SoC, wherein the determined device aging is representative of device aging within said functional module, and wherein the control module determines device aging compensation to be applied to said functional module of the SoC.

31. The system of claim 30, further comprising:
an aging compensation module that applies the device aging compensation to the functional module of the SoC, wherein the aging compensation module is tailored according to the particular function performed by the functional module.

32. The system of claim 30, further comprising:
an aging compensation module that applies the device aging compensation to the functional module, wherein the aging compensation module is tailored according to whether the functional module is digital or analog.

33. The system of claim 30, further comprising:
an aging compensation module that applies the device aging compensation to the functional module based on specific aging characteristics of the functional module.

34. The system of claim 22, wherein the reference circuit is active during a device aging measurement cycle.
